(19) United States
(12) Patent Application Publication
(10) Pub. No.: US 2009/0302915 A1
(43) Pub. Date: Dec. 10, 2009

(54) Low Power and Full Rail-to-Rail Swing Pseudo CML Latch

(76) Inventor: Sarabjeet Singh, Bangalore (IN)

Correspondence Address: IBM CORPORATION;ROCHESTER IP LAW DEPT. 917, 3605 HIGHWAY 52 NORTH, ROCHESTER, MN, 55901-7829, US

(21) Appl. No.: 12/133,573

(22) Filed: Jun. 5, 2008

(51) Int. Cl. H03K 3/00

(52) U.S. Cl. 327/218

(57) ABSTRACT

The incorporation of MOS (metal oxide semiconductor) switches in the first stage of a CML latch, which act to bring about a significant savings in current usage, and thus lower power, as well as full rail-to-rail output swing. This/these switch(es) are also used to deactivate the first stage of the circuit during the second half of a timing clock cycle, so as to permit the first stage to be activated only during the first half of a clock cycle. “Cross-coupled” inverter(s) are also used in the second stage of the circuit to provide acceptable “rail-to-rail” output voltage differential “swing” using less current. In addition, the second stage also has MOSFET switch(es) which activate only during the second half of a timing clock cycle and are deactivated during the first half of a clock cycle, which requires use of less current and thus reduces power consumption.

### FIELD OF THE INVENTION

This invention relates generally to “current mode logic” (CML) integrated circuit memory latches.

### BACKGROUND OF THE INVENTION

Complimentary metal oxide semiconductor field effect transistor (CMOS) “current mode logic” (CML) circuits are widely used for memory latches in very large scale integration (VLSI) computer chip design because they provide high switching speeds.

Conventional CMOS CML latch designs use a three-layer “staggered” transistor circuit configuration involving a “current source” transistor along with “switch” transistor(s) and a “differential transistor pair” plus a resistive output load. However, this configuration has the disadvantage(s) of being unable to provide an acceptably large “rail-to-rail” output voltage differential “swing” (when transitioning from a low level to a high level or vice versa) and also demanding excessive power consumption since the current source transistor is always “on” in an activated state.

Accordingly, a compelling need has been recognized in connection with overcoming these disadvantages.

### SUMMARY OF THE INVENTION

Broadly contemplated herein, in accordance with at least one presently preferred embodiment of the present invention, is the incorporation of MOS (metal oxide semiconductor) switches in the first stage of a CML latch, which act to bring about a significant savings in current usage in a manner to be described herebelow.

In summary, one aspect of the invention provides a high speed integrated circuit memory latch device comprising a first and second current mode logic transistor circuit arrangement, the latch device comprising: a switching arrangement acting to: selectively switch the first circuit on and off in consonance with a clock cycle; selectively switch the second circuit on and off in consonance with a clock cycle; and interrelate the switching on and off of the first and second circuits based on the clock cycle; and an arrangement in the second circuit acting to retain the output signal level.

Another aspect of the invention provides a computerized system using a high speed integrated circuit memory latch device comprising a first and second current mode logic transistor circuit arrangement, the latch device comprising: a switching arrangement acting to: selectively switch the first circuit on and off in consonance with a clock cycle; selectively switch the second circuit on and off in consonance with a clock cycle; and interrelate the switching on and off of the first and second circuits based on the clock cycle; and an arrangement in the second circuit acting to retain the output signal level.

Furthermore, an additional aspect of the invention provides a method of using a high speed integrated circuit memory latch device comprising a first and second current mode logic transistor circuit arrangement in a computerized system, the method comprising the steps of: selectively switching the first circuit on and off in consonance with a clock cycle; selectively switching the second circuit on and off in consonance with a clock cycle; interrelating the switching on and off of the first and second circuits based on the clock cycle; employing an arrangement in the second circuit acting to retain the output signal level.

For a better understanding of the present invention, together with other and further features and advantages thereof, reference is made to the following description, taken in conjunction with the accompanying drawings, and the scope of the invention will be pointed out in the appended claims.

### BRIEF DESCRIPTION OF THE DRAWINGS

FIG. 1 illustrates a conventional CMOS CML latch design.

FIG. 2 illustrates a “pseudo” CML latch design.

FIG. 3 illustrates waveforms comparing the performance of prior art and inventive (“conventional” and “new”) CML latch circuits.

### DETAILED DESCRIPTION OF THE PREFERRED EMBODIMENTS

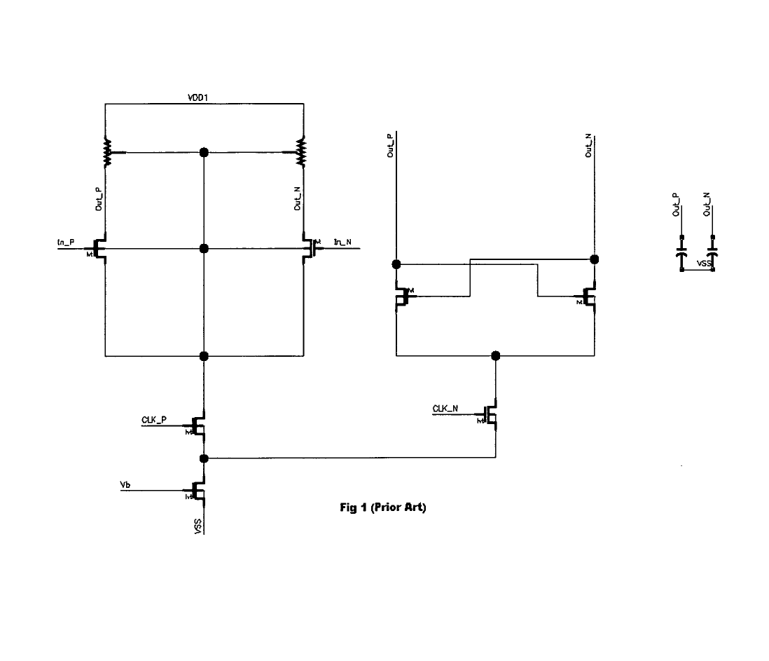

It will be readily understood that the components of the present invention, as generally described and illustrated in the Figures herein, may be arranged and designed in a wide variety of different configurations. Thus, the following more detailed description of the embodiments of the apparatus, system, and method of the present invention, as represented in FIGS. 1-3, is not intended to limit the scope of the invention, as claimed, but is merely representative of selected embodiments of the invention.

Reference throughout this specification to “one embodiment” or “an embodiment” (or the like) means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. In the following description, numerous specific details are provided, such as examples of hardware modules, hardware circuits, hardware chips, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

The illustrated embodiments of the invention will be best understood by reference to the drawings, wherein like parts are designated by like numerals or other labels throughout. The following description is intended only by way of example, and simply illustrates certain selected embodiments of devices, systems, and processes that are consistent with the invention as claimed herein.

FIG. 1 illustrates a conventional CMOS CML latch design using a three-layer “staggered” transistor circuit configuration involving a “current source” transistor along with “switch” transistor(s) and a “differential transistor pair” plus a resistive output load.

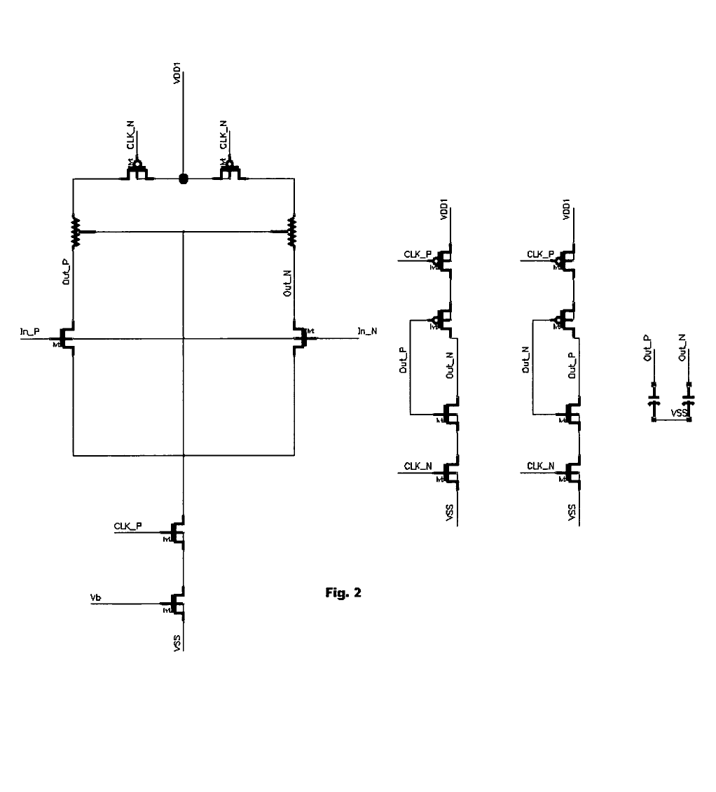

In contrast, FIG. 2 illustrates a “pseudo” CML latch design, in accordance with a preferred embodiment of the present invention, which adds a pair of MOSFET (timing clock enabled) switches in the first stage of the circuit to allow less power consumption and to provide a higher output voltage differential “swing” than conventional CML latches. Preferably, the two MOSFET switches are used to switch-off the first stage during the second half of a clock cycle, while switching-on the first stage solely during first half of a clock cycle. On the other hand, as also can be appreciated from FIG. 2, the second stage preferably employs cross-coupled inverters for achieving rail-to-rail swing using much less current. At the same time, the second stage also preferably includes MOSFET switches which, in similar fashion to the first stage, selectively switch on and off relative to the clock cycle. In this case, however, the MOSFET switches switch-on only during second half of clock cycle and are switched-off during first half of clock cycle. Here, as well, power consumption is greatly reduced via using minimal current during the second half of the clock cycle.

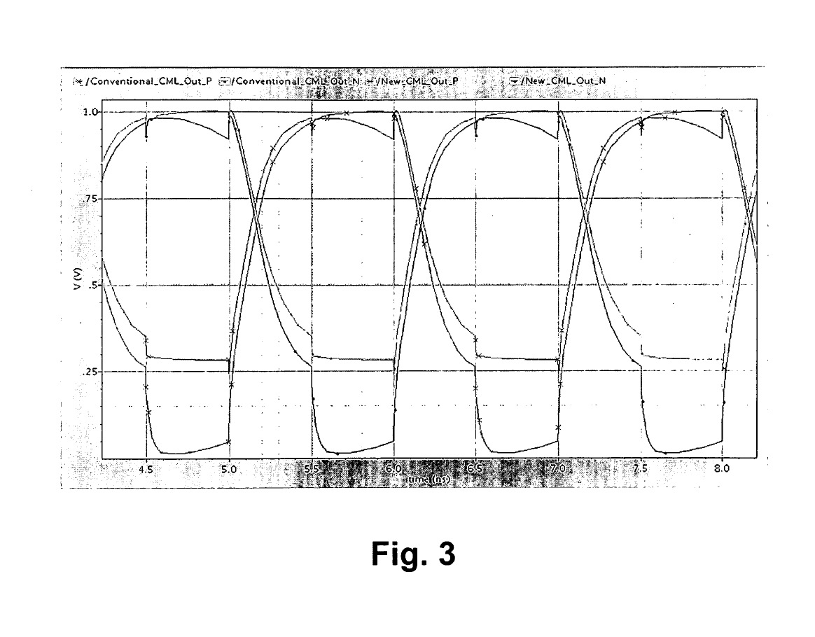

FIG. 3 shows waveforms with measurements taken at “Out_P” and “Out_N” in the circuit arrangement of FIG. 2. The waveforms in FIG. 3 convey that the prior art (“conventional”) and inventive (“new”) CML circuits present significantly different current measurements despite the same current source transistor being used for both cases, while full rail-to-rail output power swing is indeed achieved in the inventive arrangement. The conventional latch, in particular, utilizes an average current of 4.41 mA, while the inventive latch utilizes a much lower average current of 2.34 mA. Thus, the inventive latch provides a savings of approximately 47% in average current usage, implying greatly reduced power requirements. Current savings in both halves of each clock cycle can be seen from the waveforms of FIG. 3.

It is to be understood that the present invention, in accordance with at least one presently preferred embodiment, includes elements that may be implemented on at least one general-purpose computer. These may also be implemented on at least one Integrated Circuit or part of at least one Integrated Circuit. Thus, it is to be understood that the invention may be implemented in hardware, software, or a combination of both.

If not otherwise stated herein, it is to be assumed that all patents, patent applications, patent publications and other publications (including web-based publications) mentioned and cited herein are hereby fully incorporated by reference herein as if set forth in their entirety herein.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the invention.

What is claimed is:

1. A high speed integrated circuit memory latch device comprising a first and second current mode logic transistor circuit arrangement, said latch device comprising:
a switching arrangement acting to:
selectively switch the first circuit on and off in consonance with a clock cycle;
selectively switch the second circuit on and off in consonance with a clock cycle; and
interrelate the switching on and off of the first and second circuits based on the clock cycle; and
an arrangement in the second circuit acting to retain the output signal level.

2. The latch device according to claim 1, wherein said switching arrangement comprises a MOSFET switching arrangement.

3. The latch device according to claim 2, wherein said MOSFET switching arrangement comprises a pair of MOSFET switches disposed in the first circuit.

4. The latch device according to claim 2, wherein said MOSFET switching arrangement comprises a pair of MOSFET switches disposed in the second circuit.

5. The latch device according to claim 1, wherein said arrangement retaining the output signal level comprises a cross-coupled inverter arrangement.

6. The latch device according to claim 5, wherein said cross-coupled inverter arrangement comprises a pair of cross-coupled inverters disposed in the second circuit.

7. The latch device according to claim 1, wherein said switching arrangement acts to:
switch the first circuit on and the second circuit off during a first half of a clock cycle; and
switch the second circuit on and the first circuit off during a second half of a clock cycle.

8. A computerized system using a high speed integrated circuit memory latch device comprising a first and second current mode logic transistor circuit arrangement, said latch device comprising:
a switching arrangement acting to:
selectively switch the first circuit on and off in consonance with a clock cycle;
selectively switch the second circuit on and off in consonance with a clock cycle; and
interrelate the switching on and off of the first and second circuits based on the clock cycle; and
an arrangement in the second circuit acting to retain the output signal level.

9. The system according to claim 8, wherein said switching arrangement comprises a MOSFET switching arrangement.

10. The system according to claim 9, wherein said MOSFET switching arrangement comprises a pair of MOSFET switches disposed in the first circuit.

11. The system according to claim 9, wherein said MOSFET switching arrangement comprises a pair of MOSFET switches disposed in the second circuit.

12. The system according to claim 8, wherein said arrangement retaining the output signal level comprises a cross-coupled inverter arrangement.

13. The system according to claim 12, wherein said cross-coupled inverter arrangement comprises a pair of cross-coupled inverters disposed in the second circuit.

14. The system according to claim 8, wherein said switching arrangement acts to
switch the first circuit on and the second circuit off during a first half of a clock cycle; and
switch the second circuit on and the first circuit off during a second half of a clock cycle.

15. A method of using a high speed integrated circuit memory latch device comprising a first and second current mode logic transistor circuit arrangement in a computerized system, the method comprising the steps of:
selectively switching the first circuit on and off in consonance with a clock cycle;
selectively switching the second circuit on and off in consonance with a clock cycle;
interrelating the switching on and off of the first and second circuits based on the clock cycle; and
employing an arrangement in the second circuit acting to retain the output signal level.

16. The method according to claim 15, wherein said employing comprises employing a cross-coupled inverter arrangement.

17. The method according to claim 15, wherein:
said switching of the first circuit comprises switching the first circuit on during a first half of a clock cycle and off during a second half of a clock cycle; and
said switching of the second circuit comprises switching the second circuit off during a first half of a clock cycle and on during a second half of a clock cycle.
